(19) United States
(12) Patent Application Publication
(10) Pub. No.: US 2025/0024628 A1
(43) Pub. Date: Jan. 16, 2025

(54) MULTI-LEVEL MODULAR DATACENTER CONFIGURATION

(71) Applicant: OVH, Roubaix (FR)

(72) Inventors: Ali CHEHADE, Moncheaux (FR); Gregory Francis Louis BAUCHART, Wattrelos (FR); Charbel MASRI, Lille (FR)

(21) Appl. No.: 18/770,261

(22) Filed: Jul. 11, 2024

(30) Foreign Application Priority Data
Jul. 12, 2023 (EP) 23306198.5

(51) Int. Cl. H05K 7/14

(52) U.S. Cl. CPC H05K 7/1497

(57) ABSTRACT

A multi-level modular datacenter and method of installation is presented. The multi-level modular datacenter including a lower containment unit housing a first assembly of data processing equipment, an upper containment unit housing a second assembly of data processing equipment, in which the upper containment unit is arranged to be aligned and vertically disposed directly above the lower containment unit. The multi-level modular datacenter further including at least one first support structure configured to support a respective underneath area of a lateral side portion of the second containment unit and at least one second support structure configured to support a respective underneath area of a corner portion of the second containment unit. The first and second support structures are arranged to receive all weight bearing forces of the second containment unit and provide a protective vertical isolation gap between the first and second containment units.

### CROSS REFERENCE

The present application claims priority to EP Application No. 23306198.5, filed Jul. 12, 2023, entitled “MULTI-LEVEL MODULAR DATACENTER CONFIGURATION”, the entirety of which is incorporated herein by reference.

### FIELD OF TECHNOLOGY

The present technology relates to overall datacenter configurations, and in particular, to a multi-level modular datacenter configuration.

### BACKGROUND

In efforts to process vast amounts of data in near-real time, permanent datacenters house and service multitudes of racks containing electronic equipment, such as, computer server assemblies, specialized processors, memory components, high-speed network modules, etc. as well as supporting infrastructure equipment, such as, power facilities, air handling systems, liquid cooling structures, etc.

The market demand to service the ever-increasing data processing requirements eventually leads to the need of more datacenters. However, the initial investment costs along with the construction time associated with the installation of permanent datacenters can be prohibitive.

To counter the high cost of constructing permanent datacenters, various solutions have been proposed directed to the installation of “modular datacenters,” in which datacenter electronic computing equipment and supporting infrastructure equipment are incorporated in movable trailers or shipping containers. Depending on data processing demands, multiple trailers/shipping containers may be deployed and arranged in different single level geometric configurations that spread across a sizeable area. Therefore, in contrast to permanent datacenters, modular datacenters provide substantial reductions in overall construction time and installation costs to provide speedier turn-key operations.

However, a situation may exist in which certain space-limited geographical areas having high data processing needs (e.g., urban areas, research campuses, etc.), may not be able to accommodate sprawling modular datacenter configurations. It may, therefore, be desirable to provide multiple modular datacenter configurations having smaller footprints.

It is to be noted that the subject matter discussed in the background section should not be assumed to be prior art merely as a result of its mention in the background section. Similarly, the issues mentioned in the background section should not be interpreted as having been recognized in the prior art.

### SUMMARY

It is an object of the present technology to alleviate at least some of the drawbacks that prevail in the prior art.

In addressing such drawbacks, the embodiments of the present disclosure provide a multi-level modular datacenter a lower containment unit configured to house a first assembly of data processing equipment and supporting infrastructure equipment; an upper containment unit configured to house a second assembly of data processing equipment and supporting infrastructure equipment, the upper containment unit arranged to be aligned and vertically disposed directly above the lower containment unit; at least one first support structure configured to support a respective underneath area of a lateral side portion of the second containment unit; and at least one second support structure configured to support a respective underneath area of a corner portion of the second containment unit. The at least one first and second support structures being arranged to: raise the second containment unit directly above the first containment unit and receive all weight bearing forces of the second containment unit, and provide a protective vertical isolation gap between the first and second containment units.

The multi-level modular datacenter provides that the protective vertical isolation gap comprises a vertical height displacement of approximately 100 mm to approximately 500 mm to provide a preventative air layer.

The multi-level modular datacenter also provides that the at least one first support structure manifests a general A-shaped configuration and further comprises a bracket member incorporating a cross member having flanged coupling portions disposed at both ends of the cross member; and an engagement planar member fixedly attached to the cross member, the engagement planar member configured to directly interface and supportively engage the respective underneath area of the lateral side portion of the second containment unit. Additionally, the engagement planar member includes at least one fastening element for securely attaching the engagement planar member to the underside lateral portion of the upper containment unit.

The multi-level modular datacenter also provides that the at least one first support structure incorporates at least one footplate member fixedly attached to a bottom end of each respective leg forming the A-shaped configuration of the at least one first support structure. Additionally, the at least one footplate member includes an extended portion to securely couple the at least one first support structure to an underside portion of the lower containment unit.

The multi-level modular datacenter further provides that the at least one footplate member is mounted to a positioning plate including upwardly protruding anchor elements of positioning plate serve to securely couple the first support structure to an underside portion of the lower containment unit. Additionally, the positioning plate is configured to accommodate one more tilting plates for lifting a side of the lower containment unit and tilting the lower containment unit accordingly.

The multi-level modular datacenter further provides that the at least one second support structure comprises a combined arrangement between the at least one first support structure and a second frame member manifesting a general A-shaped configuration.

The multi-level modular datacenter further provides that the second frame member is securely fastened to one of the flanged coupling portions of the bracket member of the at least one first support structure. Additionally, the secure fastening of the second frame member to one of the flanged coupling portions of the bracket member comprises a threaded bolt and nut combination.

Moreover, the embodiments of the present disclosure also provide an assembly method for a multilevel modular datacenter configuration comprising a lower containment unit and an upper containment unit disposed above the lower containment unit, in which the assembly method includes determining location placement of positioning plates in accordance with dimensions and location of corner portions of the lower containment unit; installing the positioning plates at the determined placement locations; mounting footplate members of first support structures onto the corresponding positioning plates; positioning and securely coupling the lower containment unit onto the positioning plates with the correspondingly mounted footplate members of the first support structures; attaching and securely fastening second frame members to the first support structures to provide second support structures that support the upper containment unit; and positioning and securely coupling the upper containment unit onto the second support structures, such that the upper containment unit is isolated from imparting any weight bearing forces onto the lower containment unit.

The multilevel modular datacenter assembly method further including determining whether tilting of a lateral side of the lower containment unit is required; and upon determining the requirement for tilting, installing tilting plates to the positioning plates to raise a corresponding lateral side of the lower containment unit.

Implementations of the present technology each have at least one of the above-mentioned objects and/or aspects, but may not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1A depicts a perspective view of a base multilevel modular datacenter configuration, in accordance with non-limiting embodiments of the present disclosure;

FIG. 1B depicts a side elevation view of the base multilevel modular datacenter configuration, in accordance with non-limiting embodiments of the present disclosure;

FIG. 1C depicts a perspective view of a plurality of multilevel modular datacenter configurations aligned along a lateral direction, in accordance with non-limiting embodiments of the present disclosure;

FIGS. 2A and 2B depict perspective views of a first support structure, in accordance with non-limiting embodiments of the present disclosure;

FIG. 3 depicts a perspective view of a second support structure, in accordance with non-limiting embodiments of the present disclosure; and

FIG. 4 illustrates a method of assembly for multilevel modular datacenter configuration, in accordance with non-limiting embodiments of the present disclosure.

### DETAILED DESCRIPTION

The instant disclosure is directed to addressing at least some of the issues associated with space-limited geographical areas having high data processing needs that may not be able to accommodate sprawling modular datacenter configurations. In particular, the instant disclosure presents various embodiments that provide multiple modular datacenter configurations with smaller footprints.

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative systems embodying the principles of the present technology.

With these fundamentals in place, we will now consider some non-limiting examples to illustrate the implementations of the various inventive aspects of the present disclosure.

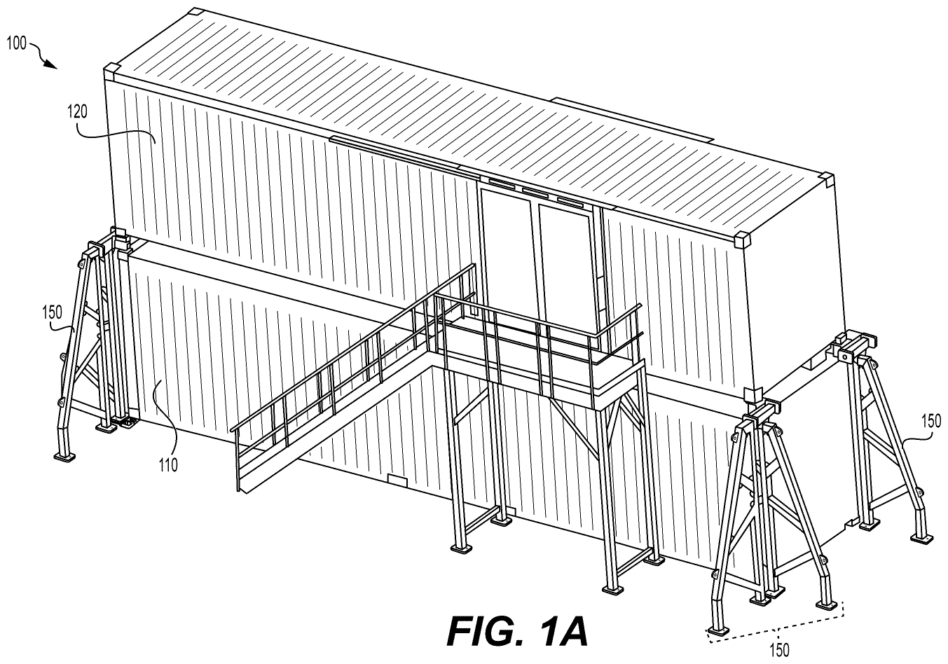

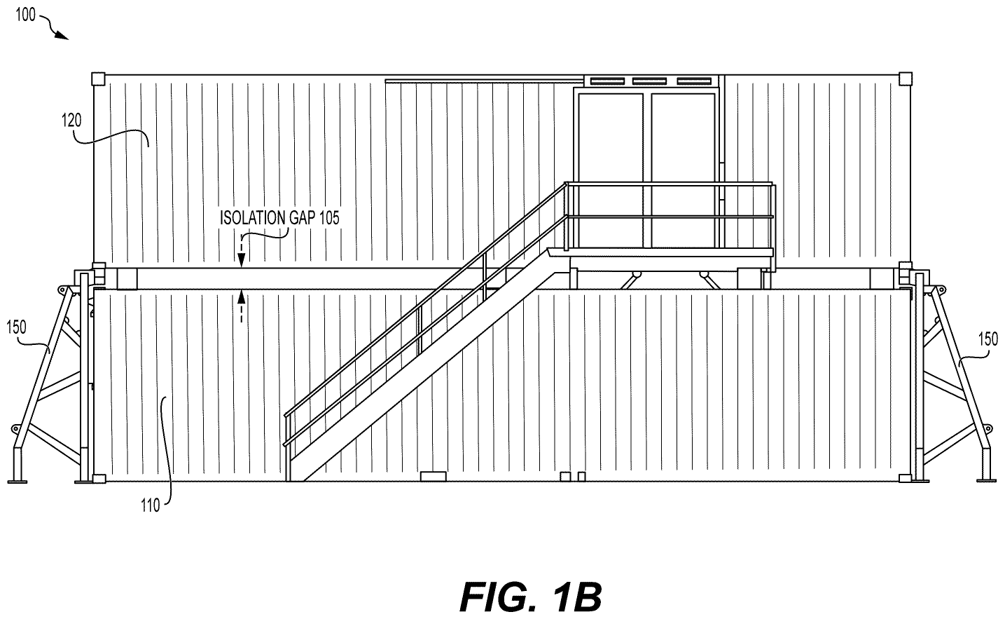

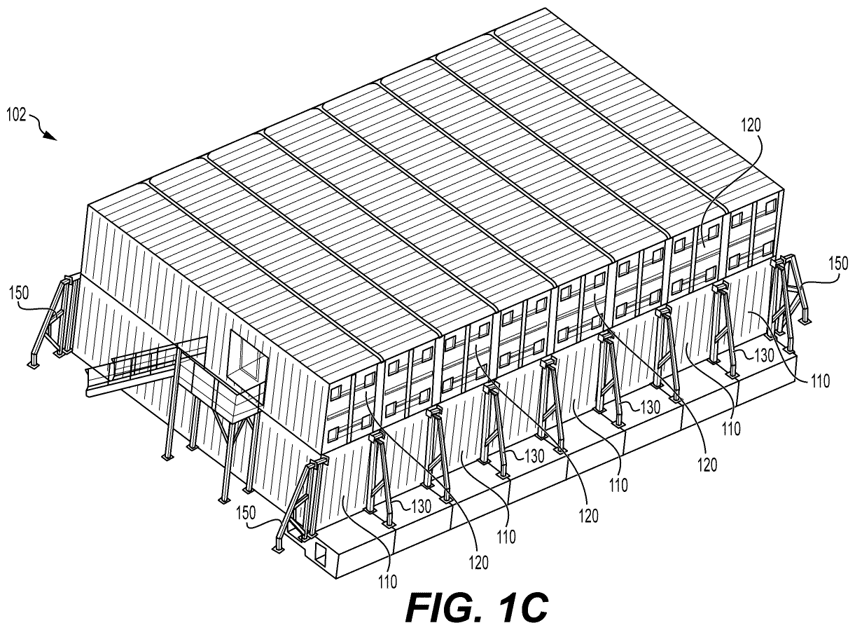

In particular, FIG. 1A depicts a perspective view of a base multilevel modular datacenter configuration 100, FIG. 1B depicts a side elevation view of the base multilevel modular datacenter configuration 100, and FIG. 1C depicts a perspective view of a plurality of multilevel modular datacenter configurations grouped as successive rows, respectively, in accordance with nonlimiting embodiments of the present disclosure.

As shown by the depicted embodiments, multilevel modular datacenter configuration 100 employs a vertically-stacked arrangement comprising a lower containment unit 110 and an upper containment unit 120 that is vertically aligned and disposed directly above the lower containment unit 110. The containment units 110, 120 may be embodied by trailers, shipping containers, or other similarly-configured structures. The vertically-stacked arrangement of containment units 110, 120 provides the benefit of a performing high volume data processing operations within a relatively limited footprint.

With this said, the containment units 110, 120 are configured to house and service an assembly of multiple racks containing electronic equipment, such as, computer server assemblies, specialized processors, memory components, high-speed network modules, etc. along with supporting infrastructure equipment, such as, power facilities, air handling systems, liquid cooling structures, etc. It will be appreciated that each of the containment units 110, 120 may incorporate different components and equipment of the overall modular datacenter system or may duplicate the same components/equipment for redundancy purposes. As such, both the first and second containment units 110, 120 incorporate one or more openings (not shown) to enable ventilation of the data processing equipment as well as accommodate the routing of associated cabling and/or piping arrangements between the containment units 110, 120 and/or to external resources.

As shown in FIGS. 1A, 1B, the vertically-stacked multilevel modular datacenter configuration 100 employs support structures 150 proximately positioned along the underside of corner portions of upper containment unit 120. Relatedly, as shown in FIG. 1C, the plurality of vertically-stacked multilevel modular datacenters configuration 102 may also employ support structures 130 proximately positioned along the underside of lateral portions of upper containment unit 120. As described in greater detail below, in use, the upper containment unit 120 is not supported by the lower containment unit 110. Rather, that the support structures 130, 150 function to carry and maintain the upper containment unit 120 above the lower containment unit 110.

As best seen in FIG. 1B, the support structures 130, 150 are configured, and operate, to raise the upper containment unit 120 above the lower containment unit 110 to produce an isolation gap 105 between the lower containment unit 110 and the upper containment unit 120. The isolation gap 105 offers several advantages: (a) prevents any weight bearing forces of the upper containment unit 120 from being imparted or directed onto the lower containment unit 110; (b) provides a protective air layer against the spread of fire, water, and/or electrical hazards between the containment units 110, 120; and (c) facilitates access by industrial equipment to install/deinstall containment units 110, 120. The vertical height displacement of isolation gap 105 may depend from mechanical properties of the material constituting a bracket member 134 (described below), such that materials with higher mechanical tensile strength may allow for a smaller isolation gap 105 height displacement that for materials having lower mechanical tensile strength. The isolation gap 105 height displacement may be arranged to be between approx. 100 mm to approx. 500 mm.

As can be seen from the figures, the support structures 130, 150 do not extend in a transverse section of the multilevel modular datacenter 100 between the lower containment unit 110 and the upper containment unit 120.

As can be seen from the figures, each support structure extends only on a corner of the lower containment unit 110 and upper containment unit 120.

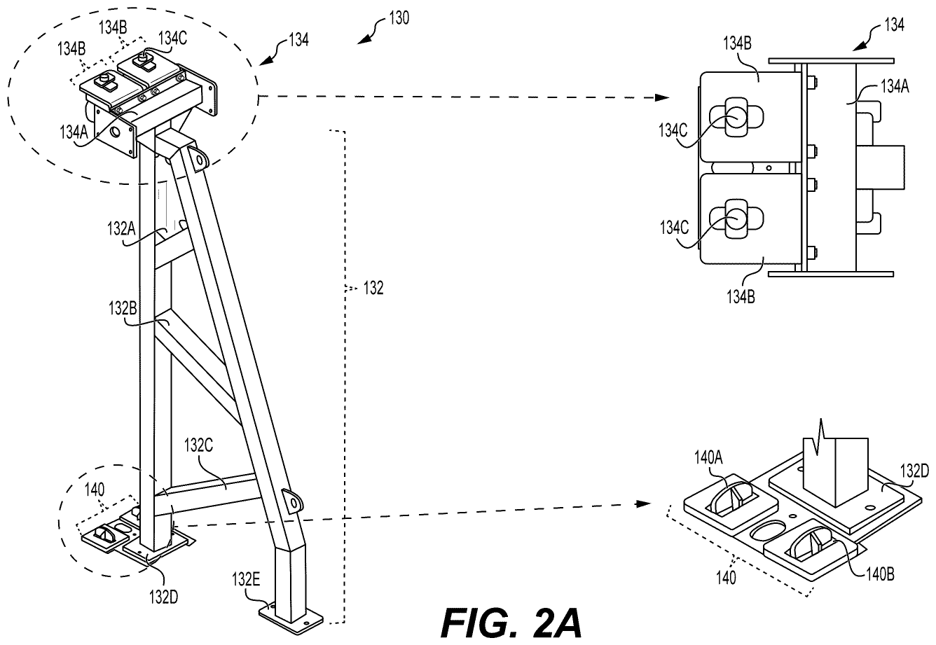

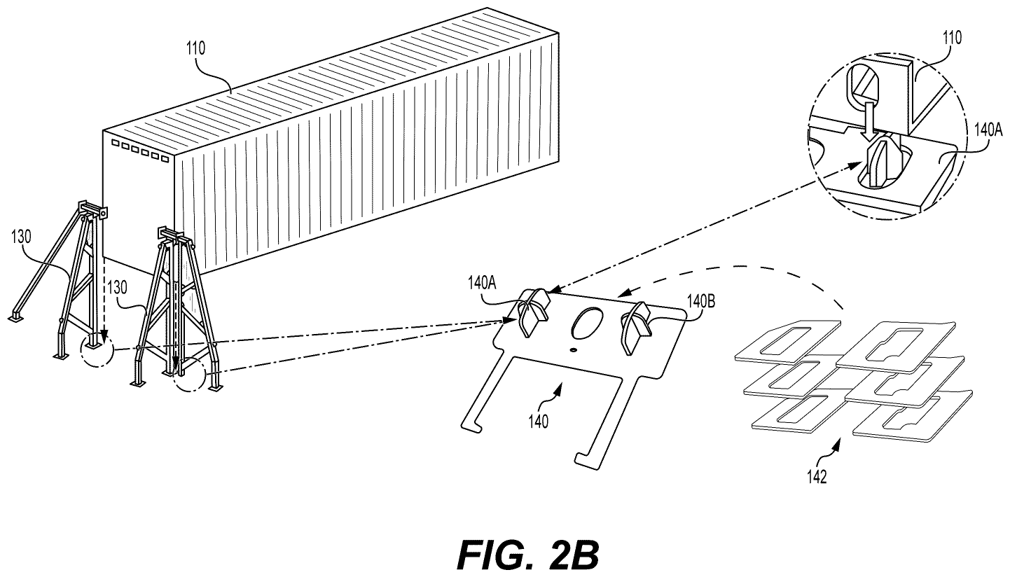

FIGS. 2A, 2B depict a perspective view of a first support structure 130 and corresponding footplate members, respectively, in accordance with non-limiting embodiments of the present disclosure. The first support structure 130 is configured, and operates, to support an underside of lateral portions of the upper containment unit 120, as best seen in FIG. 1C. In the depicted nonlimiting embodiment, the first support structure 130 comprises a main frame member 132, cross brace members 132A, 132B, 132C, a bracket member 134, and footplate members 132D, 132E.

In the depicted nonlimiting embodiment of FIG. 2A, the main frame member 132 of the first support structure 130 manifests a general “A-shaped” configuration having one or more cross brace members 132A, 132B, 132C disposed between the respective vertical legs forming the A-shaped configuration. The A-shaped configuration of the main frame member 132 provides stability and strength that is capable of handling the weight bearing force imparted by the lateral sides of the upper containment unit 120. It will be appreciated that other shape configurations/designs of the main frame member 132 may be employed, provided that such other configurations are capable of handling the weight bearing force of upper containment unit 120.

As shown, fixedly attached to a top end of the A-shaped main frame member 132 of the first support structure 130 is bracket member 134. The bracket member 134 is configured, and operates, to engage an underside portion of a lateral side of the upper containment unit 120. To this end, bracket member 134 comprises a cross member 134A incorporating flanged coupling portions disposed at both ends and one or more engagement planar members 134B fixedly attached to the cross member 134A.

As best seen in the enlarged top view cutout of bracket member 134 in FIG. 2A, two engagement planar members 134B are depicted that are configured to directly interface with, and engagingly support, an underside portion of a lateral side of a respective upper containment unit 120. Each of the engagement planar members 134B are configured to be removably attached to the first support structure 130 depending on the implementation scenarios. For example, in implementations where the first support structure 130 is to be installed to support a single upper containment unit 120 at a corner portion thereof, only one engagement planar member 134B is needed to be coupled to the first support structure 130 while a second frame member 156 (described below) is fastened the first support structure 130. And, in implementations where the first support structure 130 is to be installed to support two upper containment units 120 at respective corner portions thereof, two engagement planar members 134B are installed and fastened the first support structure 130 (i.e. one engagement planar member 134B for each of the upper containment unit 120). It can be said that an installation of the multilevel modular datacenter configuration 100 may be evolutionary. Indeed, support structures 130 disposed at corners thereof may be adjusted by disconnecting a second frame member 156 therefrom, and fastening an additional engagement planar members 134B thereto in order to support an additional upper containment unit 120.

The engagement planar member 134B includes fastening element 134C designed to securely attach the engagement planar member 134B to the underside of the upper containment unit 120. The fastening element 134C may comprise any suitable type of secure and removably attachable means, such as, for example, rotatable twist locking mechanisms, threaded bolts/nuts, etc. The fastening element 134C is aligned with a complimentary aperture (not shown) and/or a positioning plate (not shown) of the underside of the upper containment unit 120 and rotated or screwed to lock into position with the complimentary aperture. In certain implementations, the engagement planar member 134B may be equipped with one or more rectangular guiding plates 134D extending vertically upwards from planar member 134B to assist in the precise alignment of the upper containment unit 120 onto the bracket member 134 of the first support structure 130 and allow accurate placement of the complimentary aperture that is designed to mate with the fastening element 134C. For added mechanical attachment strength, the rectangular guiding plates 134D may incorporate apertures (not shown) to enable additional fastening elements, such as, bolt/nut combinations, to further secure the upper containment unit 120 onto the bracket member 134.

Moreover, as noted above, the cross member 134A of bracket member 134 incorporates flanged coupling portions at both ends. As discussed in detail below, the flanged coupling portions of cross member 134A allow for the mechanical attachment of another frame member to form a second support structure 150.

As also shown in FIG. 2A, the main frame member 132 of the first support structure 130 incorporates footplate members 132D, 132E that are configured, and operate, to establish a stable base foundation for the first support structure 130. Each of the footplate members 132D, 132E are fixedly attached to a bottom end of a respective leg forming the A-shaped main frame member 132.

While the depicted footplate members 132D, 132E are shown to manifest a rectangular shape, it will be appreciated that other configuration shapes of footplate members 132D, 132E, such as, for example, circular, elliptical, triangular, hexagonal, may be employed provided that such other configurations are capable of providing a stable base foundation.

In certain embodiments, a positioning plate 140 is used to provide accurate placement of first support structure 130. As best seen in the enlarged perspective view cutout of footplate member 132 in FIG. 2A, one of the footplate members 132D of the first support structure 130 is mounted to a positioning plate 140.

The positioning plate 140 incorporates one or more upwardly protruding anchor elements 140A, 140B. The upwardly protruding anchor elements 140A, 140B of positioning plate 140 serve to securely couple the first support structure 130 to an underside portion of the lower containment unit 110.

That is, as best seen in the depicted embodiment of FIG. 2B, one of the upwardly protruding anchor elements 140A of the positioning plate 140 operates to mate and engage a complementary-shaped aperture (not shown) on the underside corner portion of the lower containment unit 110. The protruding anchor elements 140A, 140B may be configured with a wing-shaped profile having a rotatable, threaded portion to facilitate the locked coupling of the first support structure 130 to an underside portion of the lower containment unit 110. It will be appreciated that the protruding anchor elements 140A, 140B may manifest other suitable shapes, profiles, and locking structures to provide the secure coupling of the first support structure 130 to an underside portion of the lower containment unit 110. The protruding anchor elements 140A, 140B operate to ensure that the complementary-shaped aperture (not shown) on the underside corner portion of the lower containment unit 110 is properly aligned and positioned accordingly.

In certain circumstances, such as, for example, maintenance/repair operations, fluid leakage/clean up services, etc. it may be advantageous to have one of the lateral sides of the lower containment unit 110 vertically tilted. For such purposes, tilting plates 142 may be implemented to raise a lateral side of the lower containment unit 110 that is supported by a corresponding first support structure 130 and positioning plate 140.

Accordingly, as shown by the depicted embodiment of FIG. 2B, tilting plates 142 may be installed on the positioning plate 140 to vertically tilt the corresponding lateral side of the lower containment unit 110. The tilting plates 142 are configured to have a vertical thickness of approx. 1 mm to approx. 10 mm. The number of tilting plates 142 implemented depends on the desired vertical displacement height and/or desired tilt angle of the lower containment unit 110 lateral side. The tilting plates 142 may be installed through insertion, sliding, or wedging between the top facing surface of positioning plate 140 and the interfacing bottom surface of the lower containment unit 110.

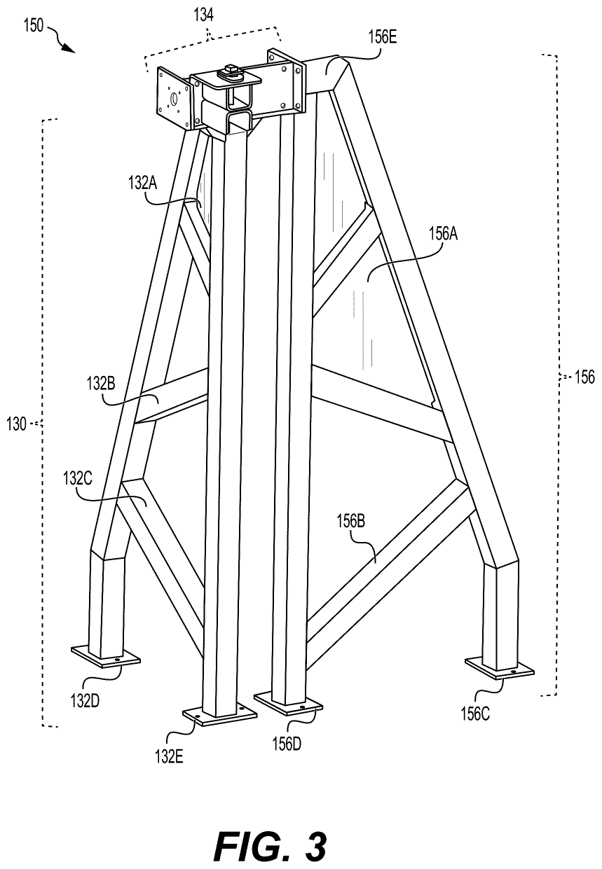

FIG. 3 depicts a perspective view of a second support structure 150, in accordance with non-limiting embodiments of the present disclosure. The second support structure 150 is configured, and operates, to support an underside portion of one or more corners of the upper containment unit 120. As shown, the second support structure 150 comprises the combination of the first support structure 130 and a second frame member 156. As detailed above, the first support structure 130 includes a footplate member 132D that is mounted to a positioning plate 140 which incorporates upwardly protruding anchor elements 140A, 140B to provide the secure coupling the first support structure 130 to an underside portion of the lower containment unit 110. With this said, and for the sake of brevity, the specific details of the first support structure 130 as described above are relied upon, except when necessary for clarification purposes.

In the depicted nonlimiting embodiment of FIG. 3, the second frame member 156 of the second support structure 130 also manifests a general “A-shaped” configuration having one or more cross brace members and/or panels 156A, 156B disposed between the respective vertical legs forming the A-shaped configuration. The A-shaped configuration of second frame member 156 provides stability and strength capable of handling the weight bearing force imparted by the corner portions of the upper containment unit 120. It will be appreciated that other shape configurations/designs of the second frame member 156 may be employed, provided that such other configurations are capable of handling the weight bearing force of upper containment unit 120.

As shown, a top end of the A-shaped second frame member 156 is securely fastened to the bracket member 134 of the first support structure 130. In particular, as noted above, the bracket member 134 incorporates flanged coupling portions on both sides of the cross member 134A to facilitate mechanical attachment. Accordingly, depending on the orientation of the corner portions of the upper containment unit 120, the second frame member 156 is securely fastened to one of the flanged coupling portions of the cross member 134A of bracket member 134 in order for the second frame member 156 to assist in supporting the weight bearing forces imparted by the upper containment unit 120 and any horizontal forces that may compromise stability. The fastening of the second frame member 156 to one of the flanged coupling portions of the cross member 134A may comprise any suitable type of secure and removably attachable means, such as, for example, threaded screws/bolts and nuts. In certain implementations, gusset plates that extend between the connecting plate of the frame member 156 and a horizontal prolongation 156E may be incorporated to increase the mechanical strength of frame member 156.

Moreover, the second frame member 156 of the second support structure 150 incorporates footplate members 156C, 156D that are configured, and operate, to establish a stable base foundation for the second support structure 150. Each of the footplate members 156C, 156D are fixedly attached to a bottom end of a respective leg forming the A-shaped second frame member 156. While the depicted footplate members 156C, 156D are shown to manifest a rectangular shape, it will be appreciated that other configuration shapes of footplate members 156C, 156D, such as, for example, circular, elliptical, triangular, hexagonal, may be employed provided that such other configurations are capable of providing a stable base foundation.

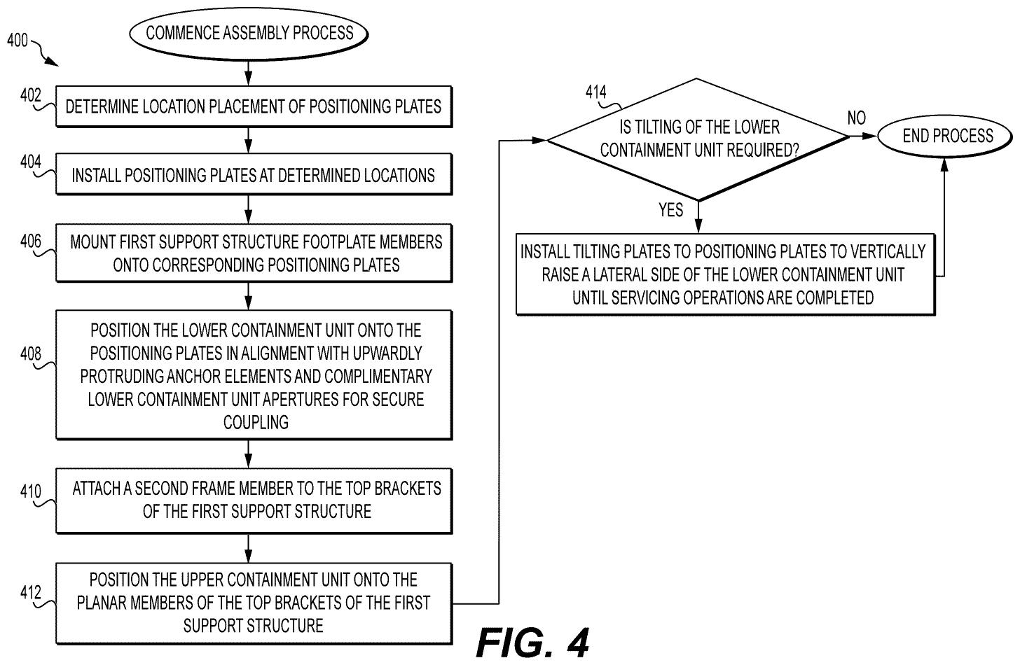

FIG. 4 illustrates a method of assembly for a multilevel modular datacenter configuration 400, in accordance with non-limiting embodiments of the present disclosure. The assembly method 400 commences at step 402 in which the location placement of the positioning plates 140 is determined. The determination of the location placement of the positioning plates 140 may be based on a variety of measurements, such as, for example, the footprint or dimensions of the lower containment unit 110, the location of the corner portions of the lower containment unit 110, etc.

At step 404, the positioning plates 140 and tilting plates 142 are installed at the determined placement locations corresponding to the corner portions of the lower containment unit 110. As noted above, tilting plates 142 may be implemented to raise a lateral side of the lower containment unit 110 that is supported by a corresponding first support structure 130 and positioning plate 140.

At step 406, footplate members 132D of the first support structures 130 are mounted onto corresponding positioning plates 140. As noted above, the first support structure 130 as well as the second support structure are configured to configured, and operate, to raise the upper containment unit 120 above the lower containment unit 110 without any weight bearing forces imparted onto the lower containment unit 110.

At step 408, the lower containment unit 110 is positioned onto the positioning plates 140 such that the upwardly protruding anchor elements 140A of the positioning plates 140 are aligned to engage complementary-shaped apertures on the underside corner portions of the lower containment units 110 to securely couple the first support structure 130 to the lower containment unit 110.

At step 410, the second frame members 156 are attached and securely fastened to corresponding top bracket members 134 of the first support structures 130 to provide a combined reinforcing support for the weight bearing corner portions of the upper containment unit 120 that is to be vertically raised above the lower containment unit 110.

At step 412, the upper containment unit 120 is positioned on top of the engagement planar members 134B of the bracket members 134 of the first support structures 130 to establish a multilevel modular datacenter configuration in which lower containment unit 110 and upper containment unit 120 are vertically arranged and positionally secured without any weight bearing forces from the upper containment unit 120 imparted onto the lower containment unit 110.

In this manner, the disclosed embodiments provide configuration and assembly of a multilevel modular datacenter capable of performing high volume data processing operations within a relatively limited footprint.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A multi-level modular datacenter, comprising:
a lower containment unit configured to house a first assembly of data processing equipment or supporting infrastructure equipment;
an upper containment unit configured to house a second assembly of data processing equipment or supporting infrastructure equipment, the upper containment unit arranged to be aligned and vertically disposed directly above the lower containment unit;
at least one first support structure configured to support a respective underneath area of a lateral side portion of the upper containment unit; and
at least one second support structure configured to support a respective underneath area of a corner portion of the upper containment unit, wherein
the at least one first and second support structures are arranged to:
raise the upper containment unit directly above the lower containment unit and receive all weight bearing forces of the upper containment unit, and
provide a protective vertical isolation gap between the lower and upper containment units.

2. The multi-level modular datacenter of claim 1, wherein the protective vertical isolation gap comprises a vertical height displacement between 100 mm to 500 mm to provide a preventative air layer against the spread of fire, water, and/or electrical hazards between the lower and upper containment units.

3. The multi-level modular datacenter of claim 1, wherein the at least one first support structure further comprises:
a bracket member incorporating a cross member having flanged coupling portions disposed at both ends of the cross member; and
an engagement planar member fixedly attached to the cross member, the engagement planar member configured to directly interface and supportively engage the respective underneath area of the lateral side portion of the upper containment unit.

4. The multi-level modular datacenter of claim 3, wherein the engagement planar member includes at least one fastening element for securely attaching the engagement planar member to the underside lateral portion of the upper containment unit.

5. The multi-level modular datacenter of claim 3, wherein the bracket member includes at) least one rectangular guiding plate extending vertically upwards from the engagement planar member to guide the upper containment unit onto precise alignment with the bracket member.

6. The multi-level modular datacenter of claim 3, wherein the at least one first support structure incorporates at least one footplate member fixedly attached to a bottom end of each respective leg forming the configuration of the at least one first support structure.

7. The multi-level modular datacenter of claim 6, wherein the at least one footplate member includes an extended portion to securely couple the at least one first support structure to an underside portion of the lower containment unit.

8. The multi-level modular datacenter of claim 6, wherein the at least one footplate member is mounted to a positioning plate that incorporates upwardly protruding anchor elements of a positioning plate that serves to securely couple the first support structure to an underside portion of the lower containment unit.

9. The multi-level modular datacenter of claim 8, wherein the positioning plate is configured to accommodate one or more tilting plates for lifting and tilting a side of the lower containment unit accordingly.

10. The multi-level modular datacenter of claim 9, wherein the one or more tilting plates comprise a vertical height displacement of 1 mm to 10 mm.

11. The multi-level modular datacenter of claim 4, wherein the at least one second support structure comprises a combined arrangement between the at least one first support structure and a second frame member.

12. The multi-level modular datacenter of claim 11, wherein the second frame member is securely fastened to one of the flanged coupling portions of the bracket member of the at least one first support structure.

13. The multi-level modular datacenter of claim 12, wherein the secure fastening of the second frame member to one of the flanged coupling portions of the bracket member comprises a threaded bolt and nut combination.

14. An assembly method for a multilevel modular datacenter configuration comprising a lower containment unit and an upper containment unit disposed above the lower containment unit, the assembly method comprising:
determining location placement of positioning plates in accordance with dimensions and location of corner portions of the lower containment unit;
determining location placement of tilting plates in accordance with lateral sides of the lower containment unit;
installing the positioning plates and tilting plates at the determined placement locations;
mounting footplate members of first support structures onto the corresponding positioning plates;
positioning and securely coupling the lower containment unit onto the positioning plates with the correspondingly mounted footplate members of the first support structures;
attaching and securely fastening second frame members to the first support structures to provide second support structures that support the upper containment unit; and
positioning and securely coupling the upper containment unit onto the second support structures, such that the upper containment unit is isolated from imparting any weight bearing forces onto the lower containment unit.

15. The multilevel modular datacenter assembly method of claim 14 further comprising:
arranging the positioning of the upper containment unit onto the second support structures, such that the upper containment unit is separated from the lower containment unit by a protective vertical isolation gap.
